(19) United States
(12) Patent Application Publication
(10) Pub. No.: US 2008/0164933 A1
(43) Pub. Date: Jul. 10, 2008

(54) METHOD AND APPARATUS FOR MULTIPLE ARRAY LOW-POWER OPERATION MODES

(75) Inventors: Michael Karl Gschwind, Chappaqua, NY (US); Robert A. Philhower, Valley Cottage, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/620,677

(22) Filed: Jan. 7, 2007

(51) Int. Cl. G11C 5/14; H03K 17/00

(52) U.S. Cl. 327/365; 365/227

(57) ABSTRACT

In an embodiment of the invention, power consumption savings are realized in an array design. Such an array design, for example and not limitation, can be used in integrated circuits, including microprocessors as memory arrays, and or instruction cache arrays. Power consumption savings are realized in the array design by utilizing multiple gating modes to allow an early gating signal, late resolving gating signals, and/or specific encodings of way select signals to gate all of the array or a portion of the array saving power when it is determined the array output is not needed.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to realizing power consumption savings in an array design, and in particular realizing power consumption savings in the array clock gating design by utilizing multiple gating modes to allow an early gating signal, late resolving gating signals, and/or encodings of way select signals to gate all of the array or a portion of the array saving power when it is determined the array output is not needed.

2. Description of Background

As integrated circuit technology has progressed so has the desire to incorporate an increasing amount of computing performance into smaller and smaller integrated circuit package sizes. With small package sizes come smaller volumes, which can make it more difficult to dissipate heat-generating power from the integrated circuit.

As such heat-dissipation problems threaten the ability to increase computing performance. In addition, design requirements that force the shrinking of overall integrated circuit package sizes only worsen the problem.

In this regard, a key challenge in the technical community is how to increase computing performance levels in view of the desire to have smaller integrated circuit package sizes.

Reducing power consumption by the pipeline front end is important as it reflects ¼ to ⅓ of the area of a modern microprocessor. The pipeline front end is characterized by the presence of a large number of memory arrays, such as including but not limited to, cache arrays, tag arrays, arrays used for address translation (TLBs, ERATs, etc), and branch prediction arrays. These arrays typically require a substantial portion of the power budget of a microprocessor. In this regard, it is not uncommon to find that the front-end arrays account for a significant fraction of the total power consumption in the microprocessor core.

This heat producing power is a limiting factor in system design. In this regard, designers of personal computers and servers are faced with the challenge of balancing between demands for higher performance where faster microprocessors fire the heat producing, power consuming arrays more often and demands for cooling these computing systems down to keep them from sustaining heat-induced damage. As such, in large server installations, it is not uncommon to find that scaling can be limited by the ability to power and cool dense populations of computers in a limited space.

Power consumption also has an impact on battery life in battery-operated devices. In this regard, higher power dissipation of a device shortens the battery life. Conversely, reducing power consumption can extend the battery life.

As one of the most power-hungry elements in a computer system, the microprocessor has been an attractive target for power reduction. The largest contributor to microprocessor power consumption is the so-called active power. Active power is the charging and discharging of internal capacitance and is proportional to fraction of cycles during which the capacitance is charged or discharged.

### SUMMARY OF THE INVENTION

The shortcomings of the prior art are overcome and additional advantages are provided through the provision of a method of array clock gating to reduce array power consumption, the method comprising selecting an event signal to consider, the event signal being operationally related to clock gating an array, the array further comprising at least one of an address decoders and at least one of a sense amplifier; determining if the event signal is available early enough to include the event signal in at least one of a clock gating expression corresponding to at least one of a late resolving gating signal effectuating gating of a portion of the array; and gating a portion of the array based on the late resolving gating signal, to reduce power consumed by the array.

System and computer program products corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution which reduces power consumption in array designs by utilizing multiple gating modes to allow early gating signal, late resolving gating signals, and encoding of way select signals to gate the array saving power when it is determined the array output is not needed.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates one example of a prior art array clock gating design;

FIG. 2 illustrates one example of an array clock gating design having multiple gating modes;

FIG. 3A illustrates one example of an array design having multiple gating modes utilizing external logic;

FIG. 3B illustrates one example of an array design having multiple gating modes with logical ‘OR’ function blocks and the pipeline latches are incorporated in the array macro;

FIG. 4 illustrates one example of a prior art routine 1000 for clock gating a prior art array 100; and

FIG. 5A-5B illustrates one example of a routine 2000 for clock gating an array wherein the array has multiple gating modes.

The detailed description explains the preferred embodiments of the invention, together with advantages and features, by way of example with reference to the drawings.

### DETAILED DESCRIPTION OF THE INVENTION

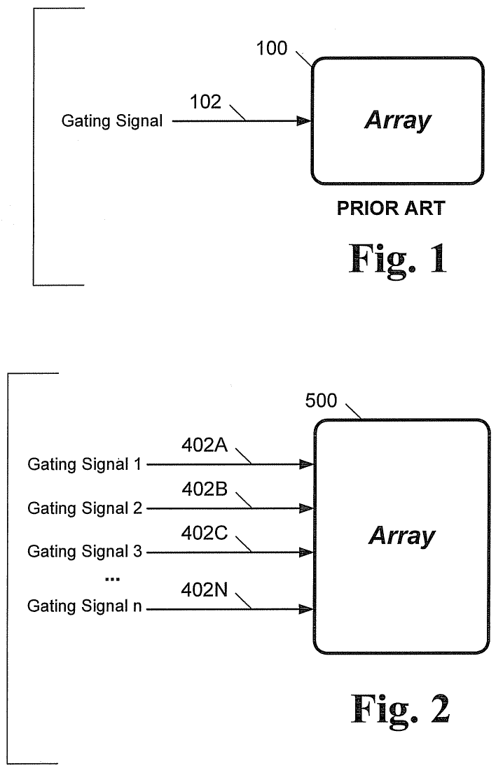

Turning now to the drawings in greater detail, it will be seen that in FIG. 1 there is illustrated one example of a prior art array clock gating design. In this regard, a microprocessor front-end contains many memory arrays, such as memory array 100. These arrays 100 can also include instruction cache arrays. The instruction cache array keeps the execution units in the rest of the microprocessor supplied with instructions to execute. The prior art array clock gating design utilizes a single gating signal 102 to turn ‘ON’ and ‘OFF’ the entire array 100. This signal is often referred to as ‘array enable’ or ‘ae’ signal.

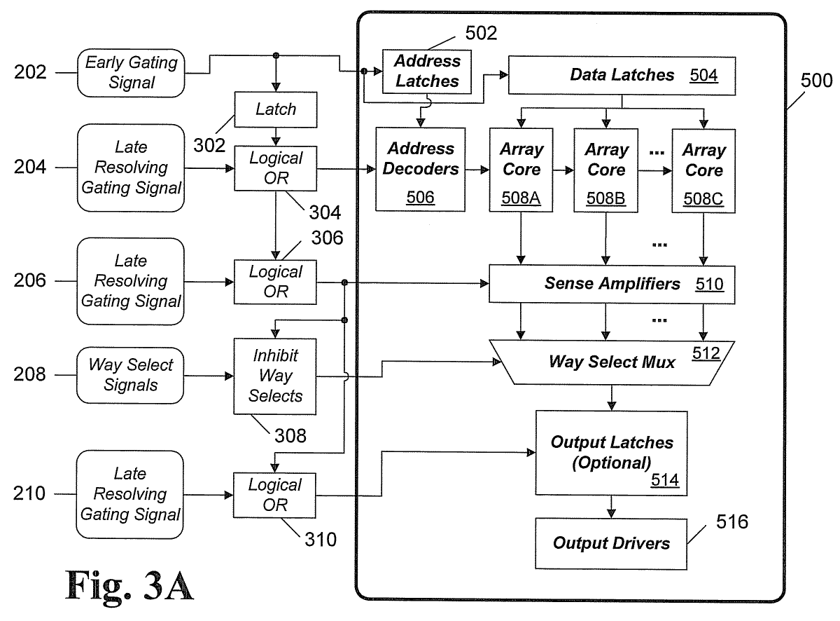

In contrast, referring to FIG. 2 there is illustrated an array clock gating design 500 having multiple gating modes. In an exemplary embodiment of the invention instead of a single gating signal of the prior art array 100, a plurality of gating signals 402A-402N are used to turn ‘ON’ and ‘OFF’ functional blocks of the array 500. These gating signals, for turning the array 500 ‘ON’ and ‘OFF’, can also be referred to as ‘array enable’ or ‘ae’ lines or signals. In this regard, power consumption of the array 500 is reduced by turning ‘OFF’ (gating) as many of the functional blocks of the array 500 as soon as it is determined that the array 500 output is not needed.

In addition to basing gating options on whether or not the output of array 500 is needed, gating determination can be made based on other factors, such as integrated circuit temperature, and/or computing performance. In this regard, gating when determined optional can be increased or decreased based in part on temperature of the integrated circuit where more gating can lower the temperature of the integrated circuit. Furthermore, gating when determined optional can be increased or decreased when computing performance is a factor, where increased gating may degrade computing performance and decreased gating may improve computing performance.

In a plurality of exemplary embodiments reducing power consumption in a plurality of arrays like array 500 can translate into a reduction of power to operate the integrated circuit containing the plurality of arrays 500. Furthermore, reducing power consumption can significantly reduce the amount of heat needing to be dissipated from the plurality of arrays 500 and ultimately reduce the amount of heat needing to be dissipated from the integrated circuit containing the plurality of arrays 500.

In addition, in battery operated devices the reduction in power required to operate a plurality of arrays 500 and ultimately the integrated circuit containing the plurality of arrays 500 can translate into significantly extending battery life.

In an exemplary embodiment in reducing power required by the array 500, it is important to turn ‘OFF’ the array 500 when it is determined that the array 500 output is not needed. As such, producing useless array 500 output wastes power without improving performance. In this regard, in an array 500 one way to reduce power consumption is to reduce the amount of capacitance charged or discharged by the array in a given clock cycle. As such, a plurality of gating signals 402A-402N can be utilized to turn ‘ON’ and ‘OFF’ the individual functional blocks of the array 500.

In an exemplary embodiment, for example and not limitation, gating signals 402A-402N illustrated as one example and generalized in FIG. 2, are similar in function to early gating signal 202, late resolving gating signal 204, late resolving gating signal 206, and late resolving gating signal 210.

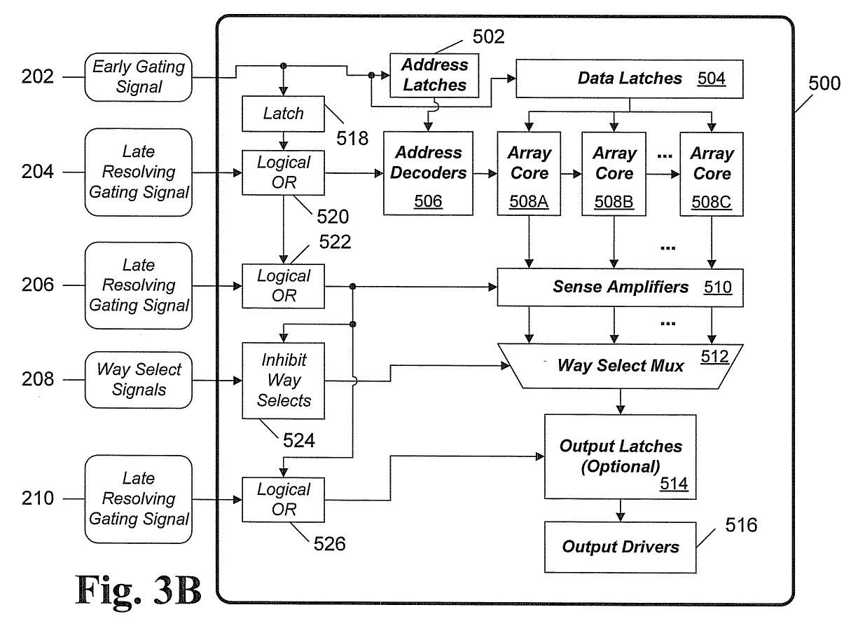

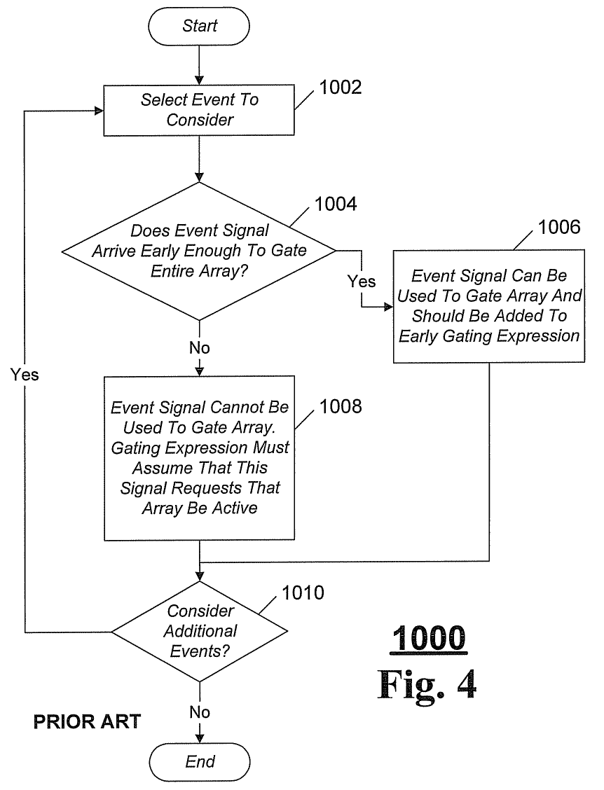

Referring to FIG. 3A there is illustrated one example of an array design having multiple gating modes utilizing external logic. Such an array design having multiple gating modes can be utilized in microprocessors, memory integrated circuits, logic integrated circuits, and or in numerous other types and kinds of integrated circuits.

In an exemplary embodiment an array 500 can have address latches 502, data latches 504, address decoders 506, a plurality of array cores 508A-508C, sense amplifiers 510, way select multiplexer 512, optionally output latches 514, and output drivers 516.

Clock gating the address latches 502 and data latches 504 with a gating signal advantageously reduces the power dissipation due to charging and discharging the clock lines driving the latches, as well as inhibiting signal transitions to the outputs of the address latches 502 and data latches 504. Inhibiting signal transitions furthermore advantageously reduces circuit switching in address decoders 506 and charging and discharging capacitive loads associated with the bit lines of array cores 508A-508C operatively coupled to data latches 504. Those skilled in the art will understand that when clock gating is not possible in a specific embodiment, then data gating to prevent output transitions from said address and data latches can be implemented based on said gating signal.

Gating address decoders 506 advantageously reduces power consumption associated with charging and discharging capacitive loads associated with the word lines of array cores 508A-508C operatively coupled to the address decoders 506. It furthermore prevents a data read cycle from occurring in responds to an activated word line with its associated power consumption due to the discharging of precharged bit line drivers, and associated effects.

Gating the sense amplifiers 510 prevent outputs from being switched, as well as reduce power consumed by said sense amplifiers. Reducing data switching advantageously reduces charging and discharging of capacitive loads, and circuit switching of static logic which may be operatively coupled to the outputs of said sense amplifiers 510.

Referring now to way select multiplexer 512, many arrays, such as array 500 include a way-select multiplexer. Way select multiplexers may be implemented using static or dynamic logic. While static logic typically offers lower power dissipation, dynamic way-select multiplexers are often chosen because they offer higher processing speeds. Way-select multiplexers are often driven by the outputs of tag matching logic. Preventing the way select multiplexer 512 from firing reduces power consumption, in particular for implementations based on dynamic logic design styles, as they reduce the need to continuously and unnecessarily charge and discharge precharge nodes. Clock gating the way select multiplexer prevents output switching, advantageously reducing power consumption.

Way select signals can have a variety of encodings—in one embodiment, they are encoded as an integer number corresponding to the cardinality of the way to be selected. Such signal may typically be decoded directly by the way select multiplexer, or by further predecoded into a 1-hot signal before being used to steer a way select multiplexer. In another embodiment, the input may advantageously already be supplied in a 1-hot representation, i.e., exactly one of the plurality of signals corresponding to the plurality of ways has a logical “1” value corresponding to that way being selected. This is particularly attractive for implementations where the way select signal is the output of a tag match circuit, and each 1-hot way indicator may directly correspond to the result of a single tag match comparator. Referring now to the 1-hot encoding for way select multiplexer, an advantageous power-saving implementation of clock gating for way-select multiplexers may be a “hot-01” representation wherein the plurality of signals corresponding to the plurality of ways to be selected from can either be in 1 hot form or a vector of all signals being zero corresponding to the absence of a way being selected when the output of the array is not required and the way select multiplexer is being gated. Referring now to the “inhibit way selects” logic 308, in one embodiment this logic receives a representation of a way indicator and generates a “hot-01” representation. In one embodiment, the way select multiplexer uses the same gating signal as the sense amplifiers 510. In another embodiment, the way select multiplexer shares gating signals with output latches 514. In yet another embodiment, a separate gating signal can be provided to offer more fine grained control of individual blocks in the array design.

With respect to the output latches 514, gating the output latches 514 saves the least amount of power, but offers the longest amount of time to calculate the clock-gating signal. Clock gating the output latches 514 prevents output switching, advantageously reducing power consumption.

Those skilled in the art will understand that other aspects of array designs may likewise be provisioned with separate and independent clock gating signals. Thus, in one embodiment, an additional gating signal may be applied to the output drivers 516 (gating signals not shown). In yet another embodiment, additional features may be present in an array and optionally provisioned with separate or shared gating signals.

In an exemplary embodiment, for example and not limitation, the determination when to gate the array can include when the array 500 is not being accessed, early gating when no conditions could force access to be required, later gating when late events become known, and when access to the same output value would occur when the array is gated.

In addition, other gateable items in many integrated circuits can include bit line pre-charge, word line, and word line latches (not shown). The exemplary embodiment of FIG. 3A also makes use of some external logic interfaced to the array 500. Such external logic includes latch 302, logical ‘OR’ 304, 306, and 310, and logic directed at inhibiting way selects 308, which correspond to the internal logic latch 518, logical ‘OR’ 520, 522, and 526, and logic directed at inhibiting way selects 524 respectively in FIG. 3B.

With respect to the address latches 502 typically when gating occurs here all downstream logic (address decoder 506, sense amplifiers 510, etc.) is gated as well, saving the most amount of power.

With respect to word line gating such gating is required later than for input latch gating. With word line gating there can be two gating options 1) prevent word lines from being asserted where bit lines do not discharge, and cells do not have to restore charge lost in read operation; and 2) clock gate latches on decoded address lines if present. In addition, the array design may also inhibit bit line pre-charge for more power savings.

In this embodiment, a plurality of gating signals can include early gating signal 202, late resolving gating signal 204, late resolving gating signal 206, and late resolving gating signal 210. Signals 204, 206, 210 can be referred to as late event signals. In general, the earlier point at which array 500 is gated will generate the largest power savings. However, gating early can be difficult in that gating early provides the least amount of time to develop the gating signal expression and gate the array 500.

In many cases during array 500 operations, gating events cannot be determined ahead of time. For example and not limitation, in certain branch execution redirects, flush redirects, exceptions, and in some cases execution unit pipelines stalls. Many of these situations cause the output of the array 500 to be required (turned ‘ON’) when it would otherwise not be required. To minimize performance loss, the array 500 must be clocked when there is any chance that a late event might require the array 500 outputs. Thus, while early gating better ensures power savings, the array 500 can rarely be gated early because of the possible of late events.

In an exemplary embodiment of the invention, the array 500 provides a plurality of gating signals at a plurality of functional blocks within the array 500. In operation, an early gating signal 202 can be applied to the data latches 504 and address latches 502. This prevents the address and data latches 502 and 504 from dissipating power when the array 500 outputs are not going to be used. This early gating signal 202 is then latched, by way of latch 302 (latch 518 in FIG. 3B), and pipelined to turn ‘OFF’ successive elements in the array 500. Subsequently, the early gating signal 202 is distributed to other elements such as, address decoder 506, the plurality of array cores 508A-508C, sense amplifiers 510, way select multiplexer 512, and (optionally) the output latches 514, thus further reducing power consumption inside the array 500. The early gating signal 202 can also inhibit the way select signal 208 to prevent power consumption in the way select multiplexer 512.

In a sharp contrast to the prior art array 100 that has no provision for late resolving clock gating signals, additional late resolving clock gating signals are incorporated into this distribution chain so that as late events are resolved, the decision can be made to turn ‘OFF’ or gate the remainder of the array 500 functional blocks. Even if this decision could not be made in time for the early gating signal 202, late events can be resolved and power can be save in array 500. These late resolving clock gating signals are connected to logical ‘OR’ functions 304, 306, 310 (520, 522, and 526 in FIG. 3B) which merge these late gating signals with the cumulative clock gating signal from earlier stages. The late resolving clock gating signals can include late resolving gating signal 204, 206, and 210.

Referring to FIG. 3B there is illustrated one example of an array 500 design having multiple gating modes with logical ‘OR’ function blocks and the pipeline latches incorporated in the array macro. In an exemplary embodiment the logical ‘OR’ function blocks and the pipeline latches are incorporated into the array macro instead of being external logic as shown in FIG. 3A. Such external logic including latch 302, logical ‘OR’ 304, 306, and 310, and inhibit way selects 308, correspond to the internal logic latch 518, logical ‘OR’ 520, 522, and 526, and logic directed at inhibiting way selects 524 respectively.

Those skilled in the art will understand that in some embodiments two or more signals may be combined into a single clock gating signal to reduce the amount of logic necessary to compute individual gating signals, while still providing multiple gating signals for an array in accordance with the present invention.

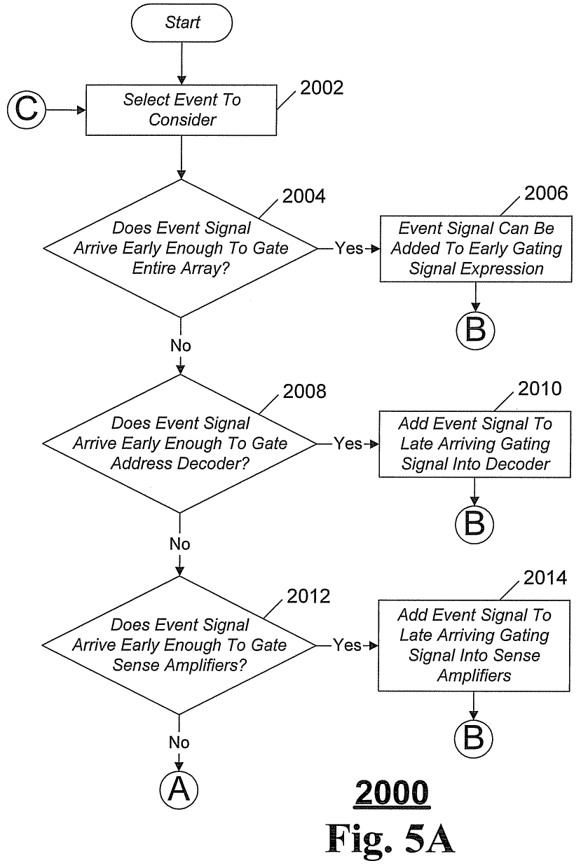

Referring to FIG. 4 there is illustrated one example of prior art method 1000 for clock gating a prior art array 100. The method also illustrates the limitations of the prior art when power savings cannot be realized in a single gated prior art array 100. The method begins in block 1002.

In block 1002 an event is selected for consideration. Processing then moves to decision block 1004.

In decision block 1004 a determination is made as to whether the event signal is available early enough to clock gate the entire array 100, thus saving power. If the resultant is in the affirmative that is the event signal is available early enough to clock gate the entire array then processing moves to block 1006. If the resultant is in the negative that is the event signal is not available early enough to clock gate the entire array then processing moves to block 1008.

In many cases during array 100 operations, gating events cannot be determined ahead of time. For example, in certain branch execution redirects, flush redirects, exceptions, and in some cases execution unit pipelines stalls. Many of these situations cause the output of the array 100 to be turned ‘ON’ when it would otherwise not be required. In effect wasting power.

In block 1006 the event signal can be used to gate array 100 and should be added to the early clock gate expression. Processing then moves to block 1010.

In block 1008 the event signal cannot be used to clock gate array 100. No power can be saved. Clock gating expression must assume that this signal requests that the entire array be active turned ‘ON’. Processing then moves to decision block 1010.

In decision block 1010 processing determines whether to consider additional events. If so, processing then returns to block 1002. Otherwise, processing ends.

In contrast to the prior art routine 1000, in an exemplary embodiment routine 2000 can be utilized with array 500 to realize significant power savings while minimizing computing performance degradation.

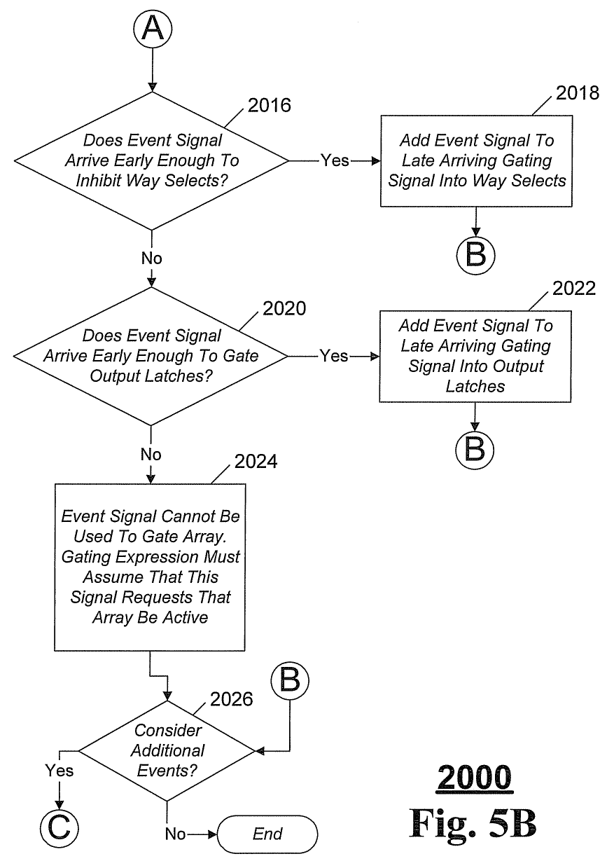

Referring to FIGS. 5A-5B there is illustrated one example of a method 2000 for clock gating an array, wherein the array has multiple gating modes.

For comparison in the prior art array 100, if the event occurs too late to gate the entire prior art array 100 then it cannot be considered and the array 100 must be active (turned ‘ON’) if that event signal could cause the output of the array 100 to be needed. In this case, late-arriving signals cannot be used to save power in the array 100. In contrast to the prior art array 100, in an exemplary embodiment of the invention, if an event signal does not arrive early enough to gate the entire array 500, method 2000 checks whether it can be used to save power by gating functional portions of less than the entire array 500 when it is determined that the output of the array 500 will not be needed.

When power can be saved in a portion of the array 500 by being gated (turned ‘OFF’) by a late arriving event signal (a way select signals 208 can be considered a late arriving event signal, and or a late resolving gating signal), the gating expression for that functional portion of the array 500 is gated, turned ‘OFF’. In this regard, each late event signal is used to save as much power as possible for that event. To clarify, late arriving events save as much power as has not already been dissipated prior to the late event signal arrival.

In addition to basing gating options on whether or not the output of array 500 is needed, gating determination can be made based in part of integrated circuit heating, and or computing performance. In this regard, gating when determined optional can be increased or decreased based in part of heating of the integrated circuit where more gating can lower the temperature of the integrated circuit. Furthermore, gating when determined optional can be increased or decreased when computing performance is a factor, where increased gating may degrade computing performance and decreased gating may improve computing performance.

In an exemplary embodiment early gating signal 202, late resolving gating signal 204, late resolving gating signal 206, way select signals 208, and late resolving gating signal 210 can be utilized in gating signal expressions to selectively save as much power as possible in array 500. The method begins in block 2002.

In block 2002 processing selects an event to consider. Processing then moves to decision block 2004.

In decision block 2004 a determination is made as to whether the event signal is available early enough to gate the clock for the entire array. If the resultant is in the affirmative that is the event signal is available early enough to gate the entire array 500 then processing moves to block 2006. If the resultant is in the negative that is the event signal is not available early enough to gate the entire array 500 then processing moves to decision block 2008.

In block 2006 the event signal can be added to the early gating signal expression for the address latches 502, and data latches 504. In this regard the array 500 is entirely gated to save power. Processing then moves to block 2026.

In decision block 2008 a determination is made as to whether the event signal is available early enough to clock gate the address decoder. If the resultant is in the affirmative that is the event signal is available early enough to clock gate the address decoder then processing moves to block 2010. If the resultant is in the negative that is the event signal is not available early enough to clock gate the address decoder then processing moves to decision block 2012.

In block 2010 processing adds the event signal to the late arriving gating signal for the address decoders 506, and where applicable the plurality of array cores 508A-508C. Processing then moves to block 2026.

In decision block 2012 a determination is made as to whether the event signal is available early enough to clock gate the sense amplifiers. If the resultant is in the affirmative that is the event signal is available early enough to clock gate the sense amplifiers then processing moves to block 2014. If the resultant is in the negative that is the event signal is not available early enough to clock gate the sense amplifiers then processing moves to decision block 2016.

In block 2014 processing adds the event signal to the late arriving gating signal for the sense amplifiers 510. Processing then moves to block 2026.

In decision block 2016 a determination is made as to whether the event signal is available early enough to inhibit the way selects. If the resultant is in the affirmative that is the event signal is available early enough to inhibit the way selects then processing moves to block 2018. If the resultant is in the negative that is the event signal is not available early enough to inhibit the way selects then processing moves to decision block 2020.

In block 2018 processing adds the event signal to a gating signal corresponding to the gating of the way select multiplexer, if such a gating signal is provided by a specific implementation for the way select multiplexer 512 (not shown in FIGS. 3A and 3B). Processing then moves to block 2026.

In decision block 2020 a determination is made as to whether the event signal is available early enough to clock gate the output latches. If the resultant is in the affirmative that is the event signal is available early enough to clock gate the output latches then processing moves to block 2022. If the resultant is in the negative that is the event signal is not available early enough to clock gate the output latches then processing moves to block 2024. The (optional) output latches 514 are optional and may or may not be present in a particular embodiment.

In block 2022 processing adds the event signal to the late arriving gating signal for the (optional) output latches 514. Processing then moves to block 2024. Decision block 2020 and 2022 can be skipped and or eliminated from routine 2000 if the array 500 does not have the optional output latches 514.

In block 2024 the event signal cannot be used to clock gate array 500. Clock gating expression must assume that this signal requests that the entire array be active. Processing then moves to decision block 2026.

In decision block 2026 processing determines whether to consider additional events. If so, processing then returns to block 2004. Otherwise, processing ends.

Those skilled in the art will understand that the method of FIGS. 5A and 5B will be suitably adapted to specific embodiments of clock gating designs within the scope of the present invention, with decision steps specific to those clock gating signals provided by a particular implementation both in terms of data availability times, and corresponding number of gating signals.

The capabilities of the present invention can be implemented in software, firmware, hardware or some combination thereof.

Referring now to a clock gating expression, a clock gating expression refers to the logic comprising the computation of a clock gating signal applied to gating signals 402A-402N of FIG. 2 and derived from a plurality of event signals, and the corresponding gating signals of FIGS. 3a and 3b. An exemplary expression may be

ifaa_gate<=(11_miss_pending OR sleep_mode OR(NOT address_valid))

A clock gating expression may be expressed as a logic expression in a design language such as VHDL, as a schematic logic rendering in a schematic tool, and will be eventually tangibly incorporated in an integrated circuit by way of automated tools or designer interaction.

While clock gating expressions have been described with respect to specific events, clock gating expressions can also include specific conditions or configuration settings as part of the determination to perform clock gating within the scope of the present invention.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of array clock gating to reduce array power consumption, said method comprising:
selecting an event signal to consider, said event signal being operationally related to clock gating an array, said array further comprising at least one of an address decoders and at least one of a sense amplifier;
determining if said event signal is available early enough to include said event signal in at least one of a clock gating expression corresponding to at least one of a late resolving gating signal effectuating gating of a portion of the array; and
gating a portion of the array based on said late resolving gating signal, to reduce power consumed by said array.

2. The method in accordance with claim 1, wherein a further determination is made with respect to said event signals to determine if said event signal is available early enough to include said event signal in at least one said clock gating expression corresponding to at least one of an early arriving gating signal effectuating gating of the entire said array, and gating the entire array based on said early arriving gating signal.

3. The method in accordance with claim 1, wherein said at least one of said late resolving gating signal is a gating signal for at least one of said address decoder.

4. The method in accordance with claim 1, wherein said at least one late resolving gating signal is a gating signal for at least one of said sense amplifier.

5. The method in accordance with claim 1, wherein at least one of said late resolving gating signal is a gating signal for at least one of a way select multiplexer, or for inhibiting way selection logic by way of modifying a way selection encoding, said array further comprising at least one of said way select multiplexer.

6. The method in accordance with claim 1, wherein at least one of said late resolving gating signal is a gating signal for at least one of an output latch, said array further comprising at least one of said output latch.

7. The method in accordance with claim 1, wherein said array is a memory array.

8. The method in accordance with claim 1, wherein said array is an instruction cache.

9. The method in accordance with claim 1, wherein said array is embodied in a microprocessor.

10. The method in accordance with claim 1, wherein said array is embodied in a memory integrated circuit.

11. The method in accordance with claim 1, further comprising:
gating said array based in part on an over temperature condition of said array.

12. A method of array clock gating to reduce array power consumption, said method comprising:
turning ‘ON’ output from an array when a gating expression operationally related to said array is not asserted, said array further comprising a plurality of functional blocks, said plurality of functional blocks including a plurality of address decoders, and a plurality of sense amplifiers; and
reducing array power consumption by gating at least one of said plurality of functional blocks in response to at least one late gating signal being asserted indicating output from said array is not needed.

13. The method in accordance with claim 12, wherein said array is a memory array.

14. The method in accordance with claim 12, wherein said array is an instruction cache.

15. The method in accordance with claim 12, wherein said array includes a way select input with encoding directed at specifying one of either a way to be selected, or no way to be selected.

16. The method in accordance with claim 12, wherein said array is embodied in a microprocessor.

17. The method in accordance with claim 12, wherein said array is embodied in a memory integrated circuit.

18. The method in accordance with claim 9, further comprising:
gating said array selectively based in part on an over temperature condition of said array.

19. A memory array having multiple power saving modes, further comprising:
multiple clock gating input signals to select one of said multiple power saving modes,
wherein each gating signal corresponds to the gating of a distinct memory array component, optionally corresponding to at least one of address and data latches, address decoders, bit lines, word lines, sense amplifiers, way select multiplexers, output latches, and output drivers.

20. The memory array in accordance with claim 19 wherein said modes correspond to clock gating more than one memory array component with each gating signal.
